(19) United States
(12) Patent Application Publication
(10) Pub. No.: US 2002/0196090 A1
(43) Pub. Date: Dec. 26, 2002

(54) Oscillator and transmitting/receiving module with dielectric resonator

(76) Inventors: Naoyuki Kurita, Kokubunji (JP); Hiroshi Kondoh, Fuchu (JP); Kenji Sekine, Hinode (JP)

Correspondence Address: Mattingly, Stanger & Malur, P.C., Suite 370, 1800 Diagonal Road, Alexandria, VA, 22314, US

(21) Appl. No.: 10/153,624

(22) Filed: May 24, 2002

(30) Foreign Application Priority Data
Jun. 22, 2001 (JP) 2001-189393

(51) Int. Cl. H03B 11/10

(52) U.S. Cl. 331/100

(57) ABSTRACT

A microwave/millimeter wave band oscillator made up of a dielectric resonator 1, and a monolithic integrated circuit 2 including an oscillator circuit is configured as follows. In a metallic area 5 immediately under substrates 2 and 3 equipped with the dielectric resonator 1, there is provided air or a material 6 having a smaller permittivity than the permittivity of the dielectric resonator, having a thickness equal to, or more than the height of the dielectric resonator 1 in the direction immediately under the substrates, and a larger cross sectional area than the cross sectional area of the dielectric resonator.

It is possible to implement an oscillator with a dielectric resonator which requires a shorter time for the installation of a tuning apparatus of the oscillating frequency and the fine-tuning step in the manufacturing of the oscillator, and can be excellently manufactured in mass production with a good yield, and a transmitting/receiving module using the same.

### BACKGROUND OF THE INVENTION

1. Field of the Invention

The present invention relates to an oscillator and a transmitting/receiving module with a dielectric resonator. More particularly, it relates to an oscillator which is used in the microwave and millimeter wave bands, and is made up of a dielectric resonator made of a high permittivity material and a monolithic integrated circuit (IC), and a transmitting/receiving module having the oscillator.

2. Description of the Related Art

An oscillator with a dielectric resonator used in the microwave and millimeter wave bands is configured as shown in a circuit diagram of FIG. 2 in the following manner. A reactance element 10 is connected between a gate of a FET 9 and a ground. A coupled line 2a is connected between a source of the FET 9 and a ground. A cylindrical dielectric resonator 1 is placed at a prescribed position of the line length and in proximity to the line 2a, so that the coupled line 2a and the dielectric resonator 1 are electromagnetically coupled. Thus, the resonator 1 is allowed to operate as a resonator. Each circuit element parameter is determined so that a negative resistance occurs in a desired frequency band. The oscillating condition holds at a desired resonant frequency uniquely determined by the diameter and the height of the dielectric resonator 1, so that an output is produced from an output terminal 2b via a matching circuit from a drain.

The dielectric resonator of the oscillator is generally mounted in the following manner. As shown in FIG. 1, on a monolithic IC substrate having a back conductor 2b, and having the coupled line 2a on the top surface, the dielectric resonator 1 is fixed in proximity to the coupled line 2a on a support 8 by using an adhesive or the like. The monolithic IC substrate is mounted on a metal base 5.

For the higher frequencies of not less than the microwave band, the chip thickness of a monolithic IC is generally from about 100 to 200 μm. Therefore, the space between the dielectric resonator 1 and the metal base 5 situated in the vicinity of the bottom surface thereof is also nearly equal to this thickness. Accordingly, the distribution of the electromagnetic field energy leaking in the space in the vicinity of the dielectric resonator 1 is in a different state from the state of distribution of the electromagnetic field energy when the dielectric resonator 1 is placed in a free space due to the presence of the metal base 5. As a result, the sensitivity to the fluctuation of the resonant frequency with respect to the fluctuation of the position in the direction of height of the dielectric resonator 1 is increased. Accordingly, in order for the resonant frequency to fall within a desired band, the adjustment of the position in the direction of height of the dielectric resonator 1 is required to be performed with very high precision.

However, the dielectric resonator 1 is generally fixed immediately on the support 8 made of a material with a low permittivity using an adhesive or the like. Particularly, for mass production, unfavorably, it is very difficult to fix the dielectric resonator 1 with high precision. Further, in order for the oscillating frequency to fall within a desired band, as is also known in the art, the oscillating frequency is fine tuned by the following apparatus. The apparatus is so configured that a ceiling made of a metal is disposed at an appropriate distance above the dielectric resonator 1, and is equipped with a device such as a screw. With such a configuration, the apparatus controls the distance between the dielectric resonator 1 and the ceiling made of a metal. However, unfavorably, the installation of such a tuning apparatus of the oscillating frequency and the step of fine tuning require much time, and incurs a high cost.

### SUMMARY OF THE INVENTION

It is therefore a primary object of the present invention to implement an oscillator which requires a shorter time for the installation of a tuning apparatus of the oscillating frequency and the fine-tuning step in manufacturing of the oscillator with a dielectric resonator, and which can be excellently manufactured in mass production with a good yield, and a transmitting/receiving module using the same.

For achieving the foregoing object, the oscillator of the present invention is configured as follows. Namely, in a microwave/millimeter wave band oscillator made up of a dielectric resonator, and a monolithic integrated circuit including an oscillator circuit, air or a material having a smaller permittivity than the permittivity of the dielectric resonator, having a thickness equal to, or more than the height of the dielectric resonator 1 in the direction immediately under the substrate, and a larger cross sectional area than the cross sectional area of the dielectric resonator is provided in a metallic area immediately under the substrate equipped with the dielectric resonator. Herein, the dielectric resonator may have either a cylindrical shape or a rectangular shape. The height of the dielectric resonator denotes the size in the direction perpendicular to the metallic area surface of the dielectric resonator. The cross sectional area of the dielectric resonator denotes the maximum area parallel to the metallic area surface of the dielectric resonator.

With the oscillator of the present invention, if the thickness of the hole (air) or the dielectric substance immediately under the substrate equipped with the dielectric resonator is equal to, or more than a prescribed value, the fluctuation of the resonant frequency with respect to the fluctuation of the mounting position of the dielectric resonator in the direction perpendicular to the monolithic integrated circuit substrate is remarkably suppressed. Therefore, the precision requirement of the fixing position of the dielectric resonator is relaxed, so that it is possible to improve the yield in mass production, resulting in a reduction of the manufacturing cost. Therefore, it is possible to manufacture the transmitting/receiving module with the microwave/millimeter wave band resonator incorporated therein at a lower cost.

The oscillator of the present invention is particularly suitable for the transmitting/receiving module to be used for a radar system for obstacle detection using a frequency within a range of from 76 GHz to 77 GHz.

These and other objects, features and advantages of the present invention will become more apparent in view of the following detailed description of the preferred embodiments in conjunction with the accompanying drawings.

### BRIEF DESCRIPTION OF THE DRAWINGS

FIG. 1 is a partially cross sectional view showing mounting of a dielectric resonator of a conventional microwave/millimeter wave band oscillator;

FIG. 2 is a circuit diagram showing a general configuration of a dielectric oscillator;

FIGS. 3A and 3B are diagrams showing a configuration of an example of a microwave/millimeter wave band oscillator in accordance with the present invention, and a transmitting/receiving module using the same;

FIG. 4 is a graph showing the state of fluctuation of the resonant frequency with respect to the fluctuation in the direction of height of the placing position of the dielectric resonator with a prior-art configuration, determined from a three dimensional electromagnetic field analysis;

FIG. 5 is a graph showing the state of fluctuation of the resonant frequency with respect to the fluctuation in the direction of height of the placing position of the dielectric resonator with the configuration of the present invention, determined from a three dimensional electromagnetic field analysis;

FIG. 6 is a graph shows the comparison among the states of fluctuation of the resonant frequency with respect to the fluctuation in the direction of height of the placing position of the dielectric resonator when the depth of an air area provided immediately under the dielectric resonator, determined from a three dimensional electromagnetic field analysis;

FIGS. 7A and 7B are schematic diagrams of a model to be subjected to the three dimensional electromagnetic field analysis; and

FIGS. 8A and 8B are diagrams showing a configuration of the transmitting/receiving module including the oscillator of the present invention mounted therein.

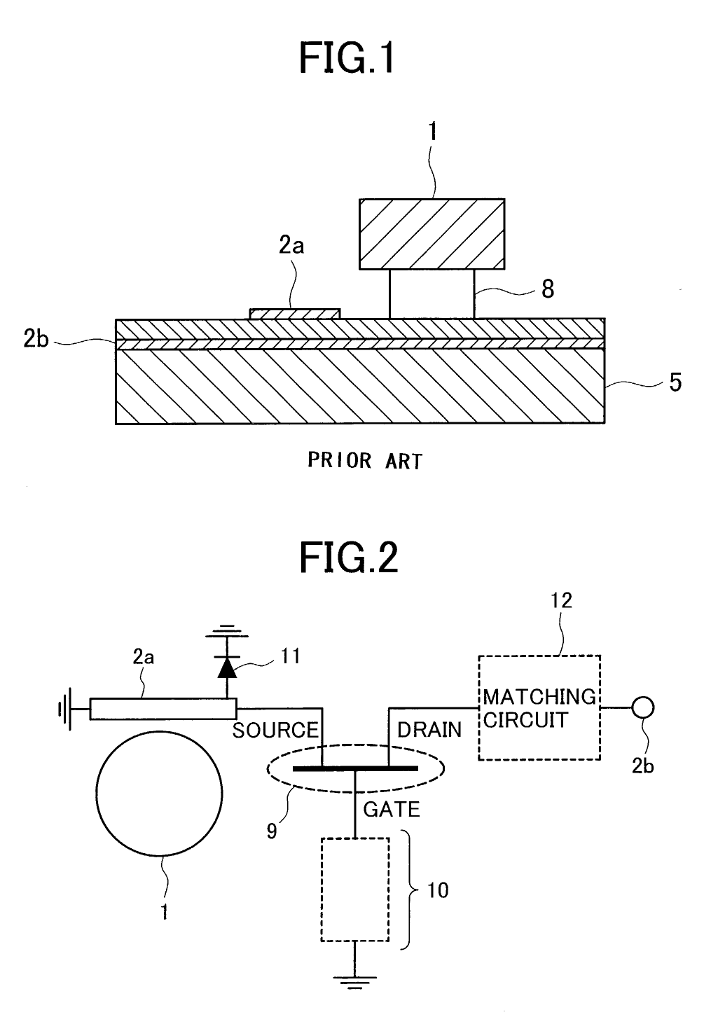

### DESCRIPTION OF THE PREFERRED EMBODIMENTS

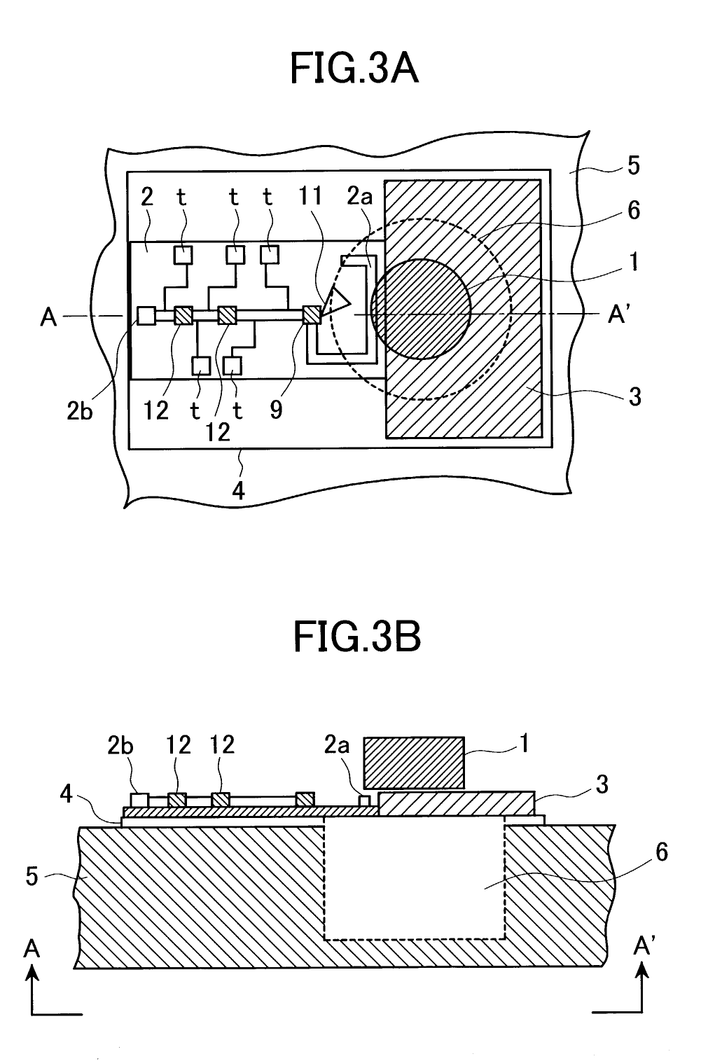

FIGS. 3A and 3B show a configuration of one embodiment of an oscillator in accordance with the present invention, and show a plan view and a partially sectional view, respectively.

On a grounded metal substrate 4, a monolithic integrated circuit (IC) 2 in which transmitting/receiving circuits such as the circuit of an oscillator are configured is placed. A dielectric resonator 1 is fixed at a position in proximity to a coupled line 2a on the monolithic IC 2. In the monolithic IC 2, the circuit shown in FIG. 2 is formed. Respective numerals correspond to the numerals of FIG. 2. A reference character “t” denotes a port for bias supplying. A cylindrical hole 6 is provided in the metal substrate 4 and a metal base 5 immediately under the dielectric resonator 1. The hole 6 may also be filled with a material with a sufficiently lower permittivity as compared with the material for the dielectric resonator 1.

The depth of the hole 6 is set to be nearly equal to, or more than the thickness of the dielectric resonator 1. Further, the diameter of the cylindrical hole 6 is larger than the diameter of the cylindrical dielectric resonator 1. In the embodiment of the present invention, the oscillator is so configured that the metal portion immediately under the resonator 1 has been removed. Therefore, as the supporting member required for fixing the resonator 1 at an appropriate position, there is disposed a plate member 3 having a size capable of covering the whole of the cylindrical hole 6, and made of a low permittivity material.

By providing the cylindrical area filled with air or the material having a sufficiently lower permittivity as compared with the dielectric resonator 1 immediately under the dielectric resonator 1, the state of distribution of the electromagnetic field energy leaking in the space in the vicinity of the dielectric resonator 1 becomes closer to the state of distribution of the electromagnetic field energy when the dielectric resonator is placed in a free space. Therefore, it is possible to reduce the variation in the resonant frequency with respect to the fixed position in the direction of height of the dielectric resonator 1 as compared with the prior-art example in which the cylindrical area 6 is not provided.

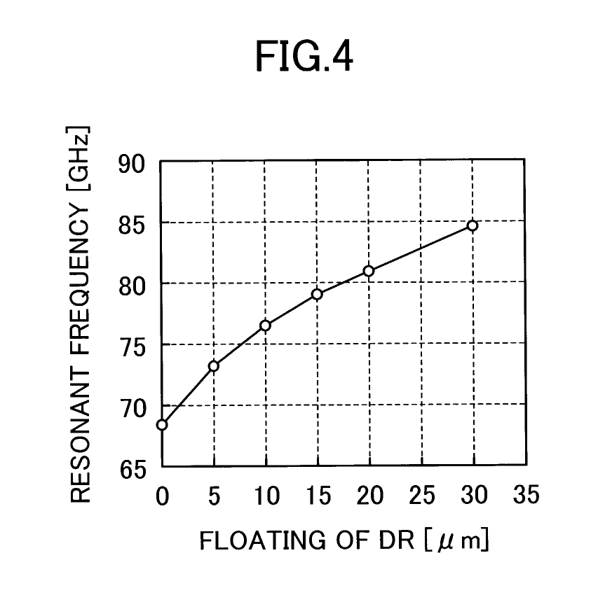

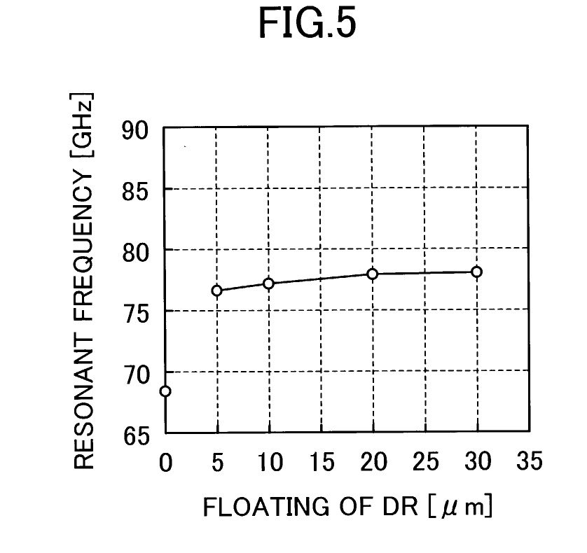

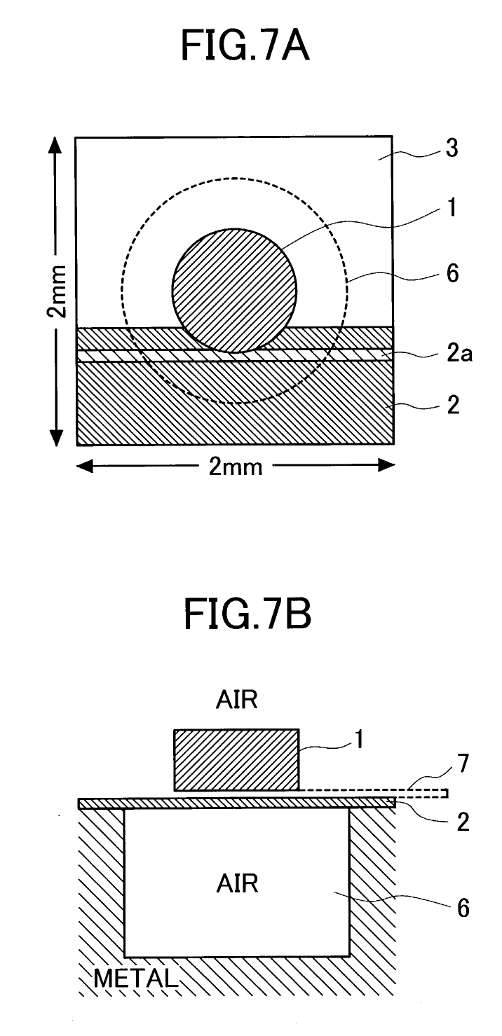

FIGS. 4 and 5 show the calculation results by a three dimensional electromagnetic field analysis simulator of the fluctuation of oscillating frequency of the oscillator with respect to the fluctuation of the fixed position in the direction of height of the dielectric resonator 1 in accordance with a prior-art and the present invention, respectively. The three dimensional electromagnetic field analysis was carried out by using the model in the form shown in FIGS. 7A and 7B. The model of FIGS. 7A and 7B is configured as follows. Assuming that the coupled line 2a on the monolithic IC 2 in the example shown in FIG. 2 is a simple microstrip transmission line, such arrangement is adopted that a part of the cylindrical dielectric resonator 1 overlaps on the line. The parameters for carrying out the calculation are as follows:

Diameter of dielectric resonator 1 . . . 0.9 mm

Height of dielectric resonator 1 . . . 0.4 mm

Permittivity of dielectric resonator 1 . . . 23.8

Permittivity of low permittivity substrate 3 . . . 6.4

Line width of microstrip line 1a . . . 60 μm

Permittivity of IC substrate 2 . . . 12.6

Diameter of area of air provided immediately under dielectric resonator 1 . . . 1.6 mm

Depth of area of air provided immediately under dielectric resonator 1 . . . 1.0 mm

Permittivity of air . . . 1.0

By using this model, the resonant frequency when the gap 7 between the dielectric resonator 1 and the low permittivity substrate 3 was changed was calculated.

FIG. 4 shows the result when the cylindrical air area 6 is not proved underneath the substrate 2. The wording “floating of DR” indicated on the abscissa denotes the gap 7 between the dielectric resonator 1 and the low permittivity substrate 3. The value plotted on the ordinate denotes the resonant frequency determined from the electromagnetic field analysis by using the model. The calculation result indicates that the resonant frequency changes by about 5 GHz if the gap 7 between the dielectric resonator 1 and the low permittivity substrate 3 changes, for example, from 5 μm to 15 μm. In contrast, as shown in FIG. 5, the calculation result when the cylindrical air area 6 has been provided underneath the substrate 3 indicates as follows: the resonant frequency fluctuates by about 300 MHz when the gap 7 between the dielectric resonator 1 and the low permittivity substrate 3 has changed from 5 μm to 15 μm as with FIG. 4. By applying the present invention thereto, the magnitude of fluctuation of the resonant frequency is suppressed down to about 1/16 of that in the prior-art example.

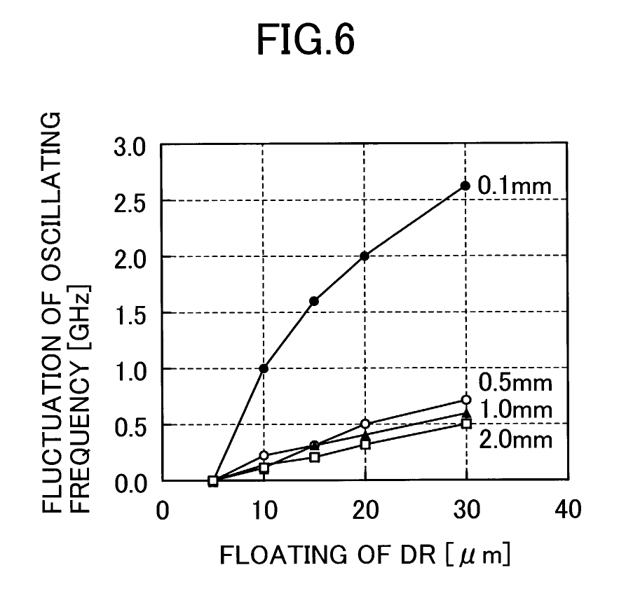

Then, the result of study on the depth of the cylindrical air area 6 to be provided immediately under the dielectric resonator 1 will be described by reference to FIG. 6. This graph shows the result of comparison among fluctuations of the resonant frequency when the depth of the cylindrical air hole 6 has been changed in the model used for the electromagnetic field analysis shown in FIGS. 7A and 7B. However, all the resonant frequencies on the ordinate are the values obtained from normalization at the value when the gap 7 between the dielectric resonator 1 and the low permittivity substrate 3 is 5 μm. For the depth of the air area 6 of 0.1 mm, if the gap 7 between the dielectric resonator 1 and the low permittivity substrate 3 changes, for example, from 5 μm to 15 μm, the resonant frequency changes by about 1.6 GHz. In contrast, for the depth of the hole 6 of 0.5 mm, the amount of fluctuation of resonant frequency is suppressed down to 500 MHz with a change in the gap 7 of from 5 μm to 15 μm. For a larger depth of the hole 6 than this, there is not observed a large difference in magnitude of fluctuation of the resonant frequency with a change in the gap 7 between the dielectric resonator 1 and the low permittivity substrate 3.

With the model used for the calculation herein shown, the thickness of the dielectric resonator 1 is set to be 0.4 mm. Therefore, if the depth of the hole 6 is nearly equal to the thickness of the dielectric resonator 1, the effect resulting from the present invention is sufficiently produced. The depth of the hole 6 is more preferably 0.5 mm or more.

In the foregoing embodiments, the shape of the hole 6 has been set to be cylindrical, but it is not limited thereto. A rectangular parallelepiped shape or other shapes equivalent thereto may also be adopted. Namely, desirably, the depth is nearly equal to, or more than the height of the dielectric resonator 1, and the plane orthogonal to the direction of depth is wider to such an extent as to receive the dielectric resonator 1 with an allowance. However, it is possible to determine the shape in consideration of the mechanical strength of the transmitting/receiving module. Namely, the effect of the present invention is produced in the following manner. The metal for ground present immediately under the dielectric resonator 1 is removed. As a result, the state of the distribution of the electromagnetic field energy leaking in the space in the vicinity of the dielectric resonator 1 is brought closer to the state of distribution of the electromagnetic field energy when the dielectric resonator 1 is placed in a free space. Therefore, even if the shape of the area filled with air or a material having a permittivity sufficiently smaller than the permittivity of the dielectric resonator 1 provided immediately under the dielectric resonator 1 is a given shape, the effect of the invention is applicable thereto.

The calculation model of the electromagnetic field analysis used for description of the application embodiment of the present invention is intended for a millimeter wave band oscillator. However, if the dimensions of the model are changed while being kept in a constant ratio, it is possible to easily apply the same effect also to an oscillator which provides an oscillation at a given frequency within a wide frequency band of from the microwave band to the millimeter wave band.

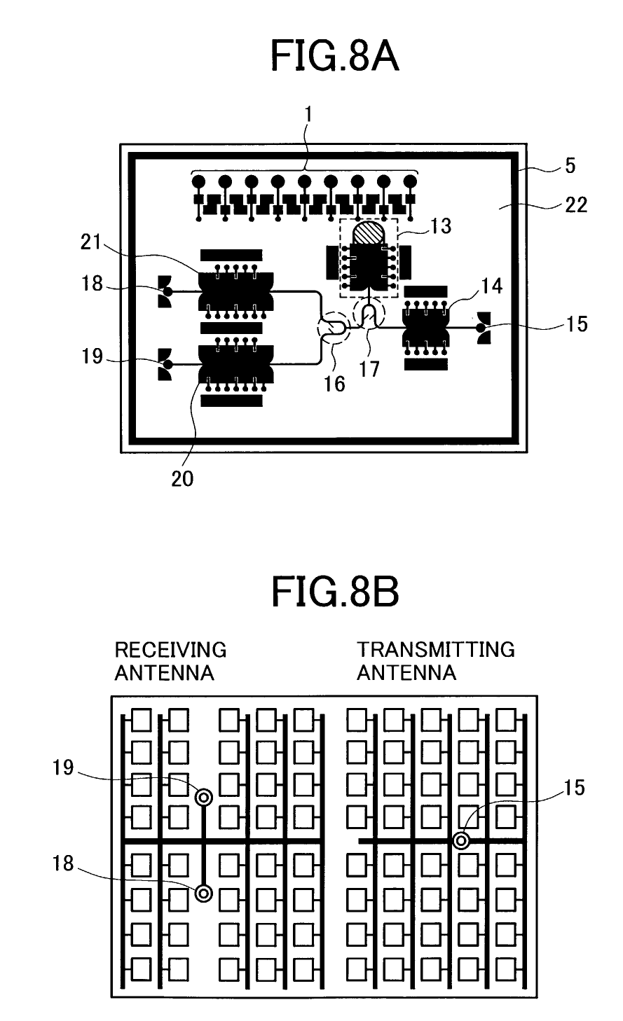

FIGS. 8A and 8B are diagrams showing the configuration of one embodiment of a transmitting/receiving module mounting the oscillator of the present invention therein. FIGS. 8A and 8B show the top view and the back view, respectively. This embodiment pertains to a transmitting/receiving module to be used for a radar system for obstacle detection to be mounted in an automobile.

In FIG. 8A, a mounting substrate 22 is formed on a metallic radar module substrate 5. The transmitting/receiving antenna as shown in FIG. 8B is formed on the back of the radar module substrate 5. The module has, on the mounting substrate 22, an integrated circuit chip 13 making up the oscillator shown in FIG. 3 above; a power amplifier chip 14 for receiving the output signal from the oscillator via a power divider 17, and amplifying it, and connecting it to the transmitting/receiving antenna via a through hole 15; and integrated circuit chips 20 and 21 connected to the oscillator via power dividers 16 and 17, and making up a mixer for performing mixing with the input signal of the receiving antenna via through holes 18 and 19. A reference character “t” denotes each power terminal of the integrated circuit chips 13, 14, 20, and 21.

As described above, in the microwave and millimeter wave band oscillator made up of the dielectric resonator 1 and the monolithic IC 2, by providing the area filled with air or the material having a sufficiently lower permittivity than the permittivity of the dielectric resonator 1 in the metallic portion immediately under the dielectric resonator 1, it is possible to reduce the fluctuation of the resonant frequency with respect to the fluctuation of the position in the direction of height of the dielectric resonator 1. As a result, when the dielectric resonator is mounted by using an adhesive or the like, it becomes easy to allow the oscillating frequency of the oscillator to fall within a desired band even for mass production. Accordingly, it is possible to improve the yield. Further, it is possible to eliminate the conventionally performed operation of controlling the oscillating frequency band. This results in a reduction of the manufacturing cost.

While the present invention has been described above in conjunction with the preferred embodiments, one of skill in the art would be enabled by this disclosure to make various modifications to this embodiments and still be within the scope and spirit of the invention as defined in the appended claims.

What is claimed is:

1. A microwave/millimeter wave band oscillator having a dielectric resonator and a monolithic integrated circuit including an oscillator circuit,
the oscillator comprising a substrate equipped with the dielectric resonator, and a metallic area immediately under the substrate, the metallic area including an area having a depth of nearly equal to, or more than the height of the dielectric resonator, and a larger cross sectional area than the cross sectional area of the dielectric resonator, and filled with air or a dielectric material with a lower permittivity than the permittivity of the dielectric resonator.

2. The microwave/millimeter wave band oscillator according to claim 1, wherein the depth is not less than 0.5 mm.

3. The microwave/millimeter wave band oscillator according to claim 1, wherein a portion, on which a line constituting the oscillator circuit is formed, of a first substrate constituting the monolithic integrated circuit, and a second substrate equipped with the dielectric resonator are interposed between the dielectric resonator and the area.

4. A microwave/millimeter wave band oscillator comprising a support substrate, a dielectric resonator, and a monolithic integrated circuit including an oscillator circuit,
the dielectric resonator being positioned on a first primary surface side of the support substrate,
a metallic area being provided on a second primary surface side of the support substrate,
a hole being provided in the vicinity of the dielectric resonator in the metallic area,
the length of the hole in the direction perpendicular to the first primary surface of the support substrate being larger than the length along the vertical direction of the dielectric resonator,
the area of the cross section of the hole parallel to the first primary surface of the support substrate being larger than the area of the cross section of the dielectric resonator, and
the hole being filled with air or a dielectric material with a lower permittivity than the permittivity of the dielectric resonator.

5. The microwave/millimeter wave band oscillator according to claim 4, wherein the area of the cross section of the hole parallel to the first primary surface of the support substrate is the area of such a cross section that the distance from the dielectric resonator is the shortest.

6. The microwave/millimeter wave band oscillator according to claim 4, wherein the length of the hole along the direction perpendicular to the first primary surface is not less than 0.5 mm.

7. The microwave/millimeter wave band oscillator according to claim 1, wherein the oscillating frequency of the oscillator circuit falls within a range of from 76 GHz to 77 GHz.

8. A transmitting/receiving module having a microwave/millimeter wave band oscillator, and a processing circuit for performing a processing of a transmitting/receiving signal using a signal from the oscillator,
the microwave/millimeter wave band oscillator comprising a support substrate, a dielectric resonator, and a monolithic integrated circuit including an oscillator circuit,
the dielectric resonator being positioned on a first primary surface side of the support substrate,
a metallic area being provided on a second primary surface side of the support substrate,
a hole being provided in the vicinity of the dielectric resonator in the metallic area,
the size of the hole along the direction perpendicular to the primary surface of the support substrate being larger than the size along the vertical direction of the dielectric resonator,
the area of the cross section of the hole parallel to the primary surface of the support substrate being larger than the area of the cross section of the dielectric resonator, and
the hole being filled with air or a dielectric material with a lower permittivity than the permittivity of the dielectric resonator.

9. The transmitting/receiving module according to claim 8, being configured so as to be used for a radar system for obstacle detection, and further comprising a transmitting/receiving antenna connected to the processing circuit formed on the metallic area.
